(19) United States
(12) Patent Application Publication
(10) Pub. No.: US 2026/0191097 A1
(43) Pub. Date: Jul. 2, 2026

(54) ELECTRONIC DEVICE

(71) Applicant: Advanced Semiconductor Engineering, Inc., Kaohsiung (TW)

(72) Inventors: Hai-Ming CHEN, Kaohsiung (TW); Chang-Yu LIN, Kaohsiung (TW); Pei-Jung YANG, Kaohsiung (TW); Chi-Han CHEN, Kaohsiung (TW); Hung-Yi LIN, Kaohsiung (TW)

(73) Assignee: Advanced Semiconductor Engineering, Inc., Kaohsiung (TW)

(21) Appl. No.: 19/002,663

(22) Filed: Dec. 26, 2024

(51) Int. Cl. H01L 25/16; H01L 23/00; H01L 23/31

(52) U.S. Cl. CPC H10W 90/00; H10W 42/121; H10W 74/111

(57) ABSTRACT

An electronic device is provided. The electronic device includes a photonic component and a reinforcement module. The reinforcement module is disposed over a first surface of the photonic component and is configured to reduce a warpage of the photonic component. The reinforcement module includes a functional element and a non-functional element. The functional element and the non-functional element collectively construct a continuous structure in a direction substantially parallel to the first surface of the photonic component.

### BACKGROUND

### 1. Technical Field

The present disclosure relates generally to an electronic device.

### 2. Description of the Related Art

Currently, a fiber array unit (FAU) may be disposed adjacent to an edge of a photonic IC (PIC) in an electronic device for optical transmission through edge coupling. With the applications of such electronic device increase and the size of the electronic device decreases, there is an increasing need to improve the optical alignment and the reliability of the electronic device including the FAU and the PIC.

### SUMMARY

In one or more arrangements, an electronic device includes a photonic component and a reinforcement module. The reinforcement module is disposed over a first surface of the photonic component and is configured to reduce a warpage of the photonic component. The reinforcement module includes a functional element and a non-functional element. The functional element and the non-functional element collectively construct a continuous structure in a direction substantially parallel to the first surface of the photonic component.

In one or more arrangements, an electronic device includes a photonic component and a reinforcement module. The reinforcement module is configured to reduce a deformation of the photonic component. The reinforcement module includes a functional element and a first reinforcement element. The functional element is connected to the first reinforcement element.

In one or more arrangements, an electronic device includes a photonic component and a reinforcement module. The reinforcement module includes a first electronic component and is disposed over the photonic component. The reinforcement module is configured to apply a supporting force along a surface of the photonic component continuously to prevent the photonic component from being cracked.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1A illustrates a data communication system in accordance with some arrangements of the present disclosure.

FIG. 1B is a top view of an electronic device in accordance with some arrangements of the present disclosure.

FIG. 1C is a cross-section of an electronic device in accordance with some arrangements of the present disclosure.

FIG. 1D is a top view of an electronic device in accordance with some arrangements of the present disclosure.

FIG. 1E is a cross-section of an electronic device in accordance with some arrangements of the present disclosure.

FIG. 1F is a cross-section illustrating a data communication system in accordance with some arrangements of the present disclosure.

FIG. 2 is a cross-section of an electronic device in accordance with some arrangements of the present disclosure.

FIG. 2A is a cross-section of an electronic device in accordance with some arrangements of the present disclosure.

FIG. 2B is a perspective view of an electronic device in accordance with some arrangements of the present disclosure.

FIG. 2C is a cross-section of an electronic device in accordance with some arrangements of the present disclosure.

FIG. 2D is a perspective view of an electronic device in accordance with some arrangements of the present disclosure.

FIG. 2E is a cross-section of an electronic device in accordance with some arrangements of the present disclosure.

FIG. 2F is a perspective view of an electronic device in accordance with some arrangements of the present disclosure.

FIG. 3A is a cross-section of an electronic device in accordance with some arrangements of the present disclosure.

FIG. 3B is a cross-section of an electronic device in accordance with some arrangements of the present disclosure.

FIG. 3C is a cross-section of an electronic device in accordance with some arrangements of the present disclosure.

FIG. 4A, FIG. 4B, FIG. 4C, FIG. 4D, FIG. 4E, FIG. 4F, FIG. 4G, FIG. 4H, FIG. 4I, FIG. 4J, FIG. 4K, and FIG. 4L show simulation results of warpage of electronic devices in accordance with some arrangements of the present disclosure.

FIG. 5A, FIG. 5B, FIG. 5C, FIG. 5D, FIG. 5E, FIG. 5F, and FIG. 5G illustrate various stages of an exemplary method for manufacturing an electronic device in accordance with some embodiments of the present disclosure.

FIG. 6A, FIG. 6B, FIG. 6C, FIG. 6D, FIG. 6E, FIG. 6F, FIG. 6G, and FIG. 6H illustrate various stages of an exemplary method for manufacturing an electronic device in accordance with some embodiments of the present disclosure.

FIG. 7A, FIG. 7B, FIG. 7C, FIG. 7D, FIG. 7E, FIG. 7F, and FIG. 7G illustrate various stages of an exemplary method for manufacturing an electronic device in accordance with some embodiments of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

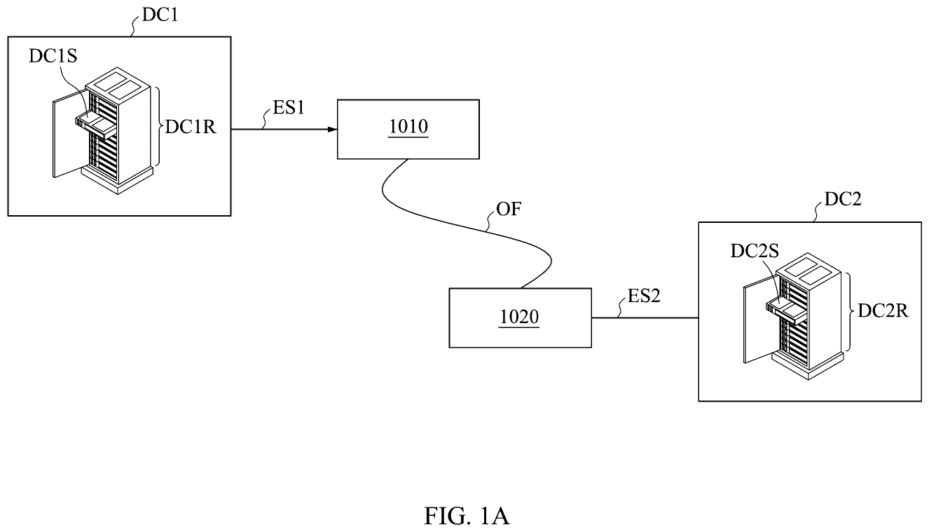

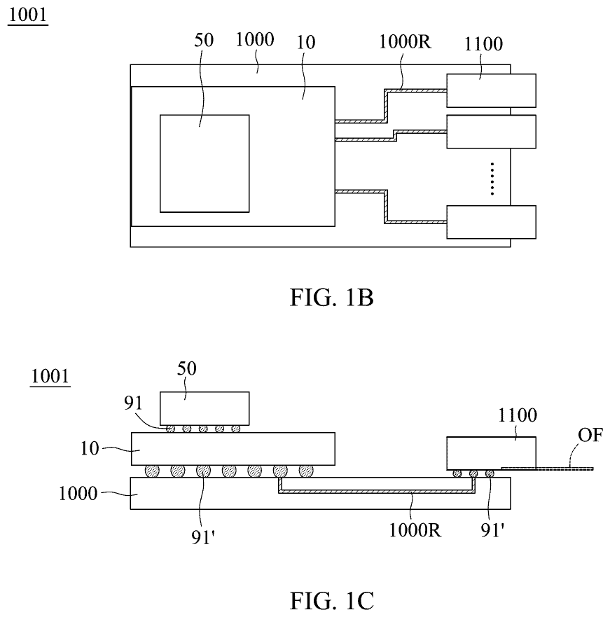

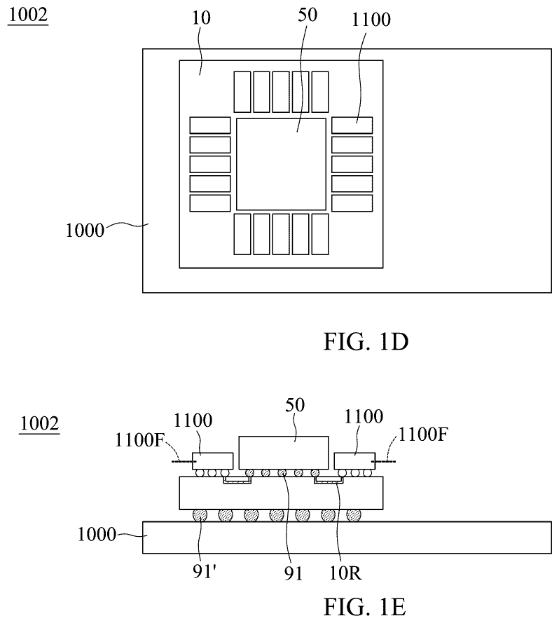

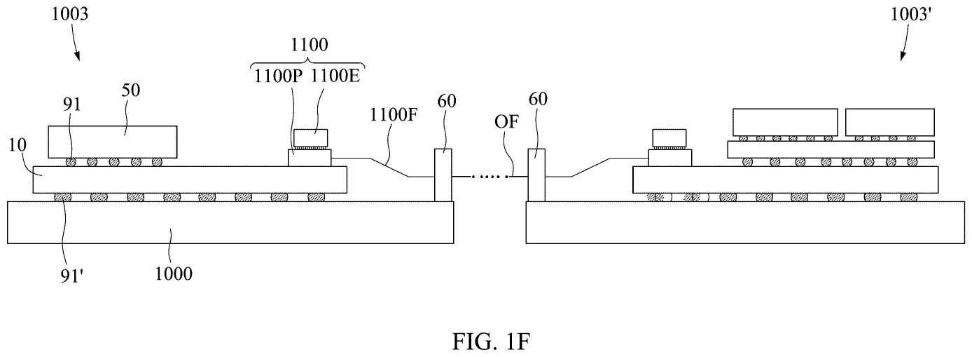

FIG. 1A illustrates a data communication system in accordance with some arrangements of the present disclosure. Data communication between a data center DC1 and a data center DC2 may be achieved by optical communication through at least an optical transmitter module 1010, an optical receiving module 1020, and one or more optical fibers OF. The data center DC1 may include a server rack DC1R including servers DC1S, and the data center DC2 may include a server rack DC2R including servers DC2S.

Due to the significantly higher bandwidth of optical signals compared to electrical signals, optical signals are used for transmission between servers of data centers DC1 and DC2. Electrical signals ES1 including on and off signals from the server of the data center DC1 may be converted to optical signals including light and dark signals by the optical transmitter module 1010 through the optical fibers OF. At the receiving end, the optical receiver module 1020 may convert the optical signals with the light and dark signals back into the electrical signals ES2 including on and off signals.

FIG. 1B is a top view of an electronic device 1001 in accordance with some arrangements of the present disclosure. FIG. 1C is a cross-section of an electronic device 1001 in accordance with some arrangements of the present disclosure. FIG. 1C may be a cross-section of the electronic device 1001 illustrated in FIG. 1B. The electronic device 1001 may be at least one of the optical transmitter module 1010 and the optical receiving module 1020.

The electronic device 1001 may include a substrate 1000, a substrate 10 and an optical module 1100 over and connected to the substrate 1000 through electrical contacts 91′, and an electronic component 50 over and electrically connected to the substrate 10 through electrical contacts 91. The optical module 1100 may be connected to optical fibers OF. The substrate 1000 may be or include a printed circuit board (PCB) or a system board, and the substrate 1000 may include conductive structure 1000R electrically connecting the substrate 10 to the optical module 1100. The electronic component 50 may be or include a switch chip. The optical module 1100 may be configured to provide a photoelectric conversion. The optical module 1100 may be or include an optical engine. In some arrangements, the electronic device 1001 serving as an optical transmitter module or an optical receiving module may include one or more pluggable optical modules (e.g., the optical module 1100). However, the distance between the electronic component 50 (or the switch chip) and the optical module 1100 (or the pluggable optical module) is relatively far, resulting in larger overall component size and higher power consumption.

FIG. 1D is a top view of an electronic device 1002 in accordance with some arrangements of the present disclosure. FIG. 1E is a cross-section of an electronic device 1002 in accordance with some arrangements of the present disclosure. FIG. 1E may be a cross-section of the electronic device 1002 illustrated in FIG. 1D. The electronic device 1002 may be at least one of the optical transmitter module 1010 and the optical receiving module 1020.

The electronic device 1002 may include a substrate 1000, a substrate 10 over and electrically connected to the substrate 1000 through electrical contacts 91′, and optical modules 1100 and an electronic component 50 over and connected to the substrate 10 through electrical contacts 91. The optical module 1100 may be connected to optical fibers 1100F. The substrate 1000 may be or include a printed circuit board (PCB) or a system board. The electronic component 50 may be or include a switch chip. The optical module 1100 may be configured to provide a photoelectric conversion. The optical module 1100 may be or include an optical engine. The substrate 10 may include a conductive structure 10R electrically connecting the electronic component 50 to the optical modules 1100.

The electronic device 1002 may feature a co-packaged optics (CPO) architecture. By utilizing mature silicon wafer and semiconductor processes, the previously separate electronic component 50 and optical modules 1100 can be integrated into a miniaturized chip (such as the electronic device 1002), which is known as silicon photonics technology. The integration of the electronic component 50 and the optical modules 1100 into the electronic device 1002 offers advantages of smaller component size and lower power consumption. The electronic device 1002 can be applied in data centers, suitable for short-distance data transmission, and can also be used for long-distance data transmission via fiber optic networks.

FIG. 1F is a cross-section illustrating a data communication system in accordance with some arrangements of the present disclosure. FIG. 1F may illustrate a data communication between electronic devices 1003 and 1003′. The data communication system may include electronic devices 1003 and 1003′, optical components 60, and optical fibers OF.

The electronic devices 1003 and 1003′ each may include a substrate 1000, a substrate 10 over and electrically connected to the substrate 1000 through electrical contacts 91′, and at least an optical module 1100 and an electronic component 50 over and connected to the substrate 10 through electrical contacts 91. The optical module 1100 may be connected to optical fibers 1100F. The substrate 1000 may be or include a printed circuit board (PCB) or a system board. The electronic component 50 may be or include a switch chip. The optical module 1100 may be configured to provide a photoelectric conversion. The optical module 1100 may be or include an optical engine. The optical module 1100 may include a photonic component 1100P (e.g., a photonic integrated circuit (PIC)) and an electronic component 1100E (e.g., an electronic integrated circuit (EIC)) electrically connected to the photonic component 1100P. The substrate 10 may include a conductive structure 1 electrically connecting the electronic component 50 to the optical modules 1100. The electronic devices 1003 and 1003′ may feature CPO architectures. The electronic devices 1003 and 1003′ can be applied in data centers and can also be used for long-distance data transmission via fiber optic networks (e.g., through the optical components 60 and the optical fibers OF).

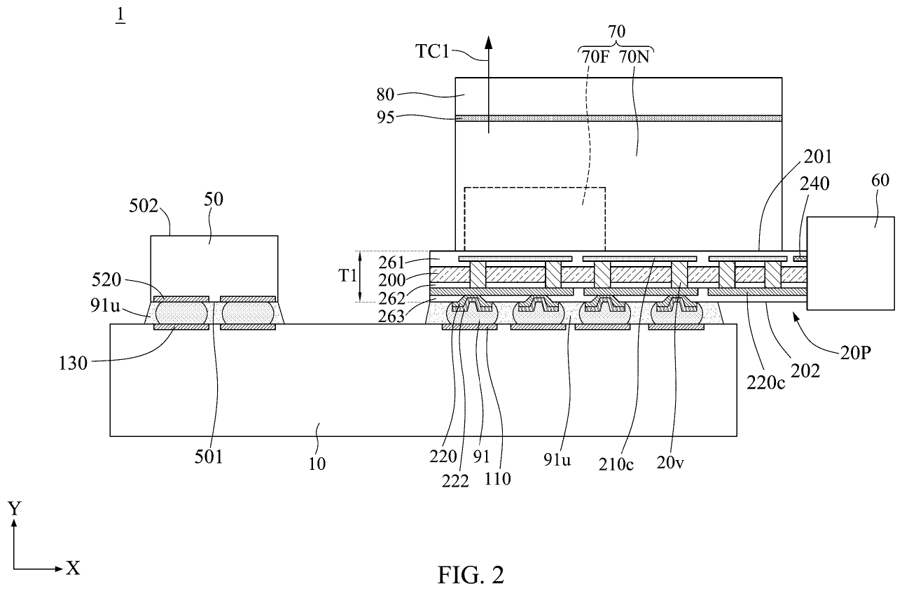

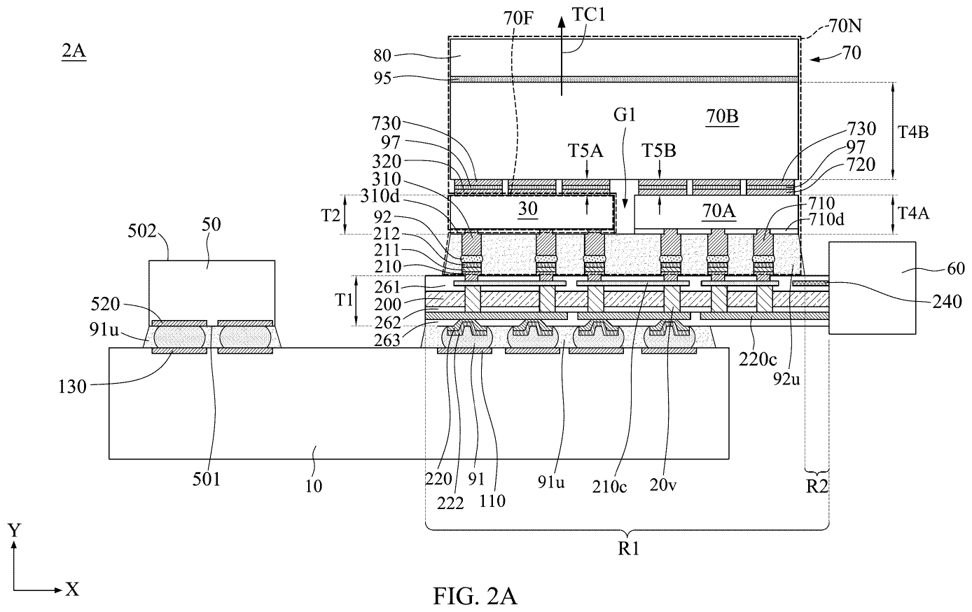

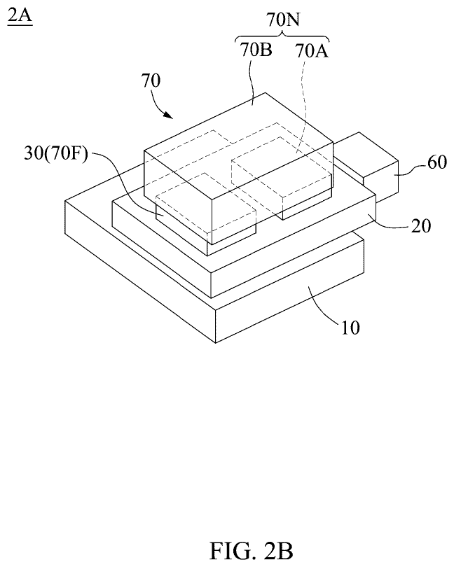

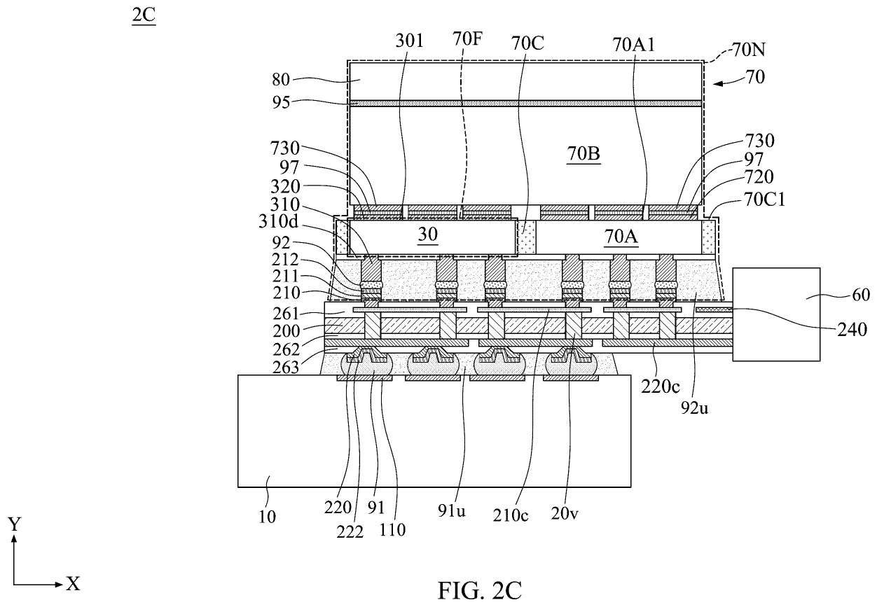

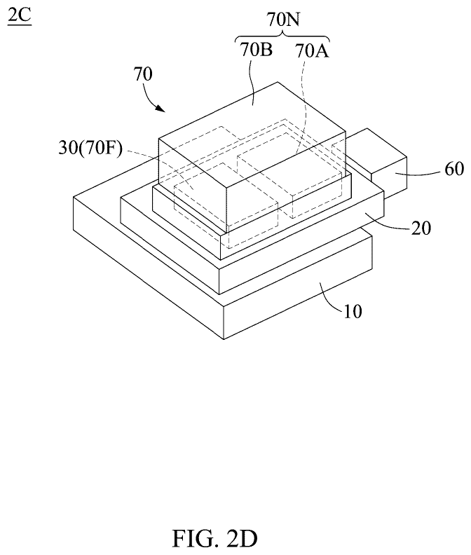

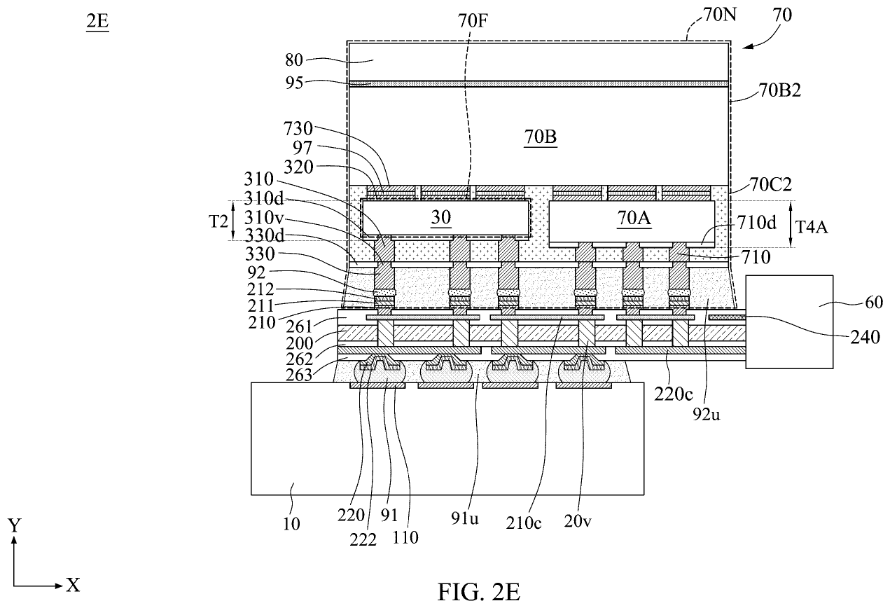

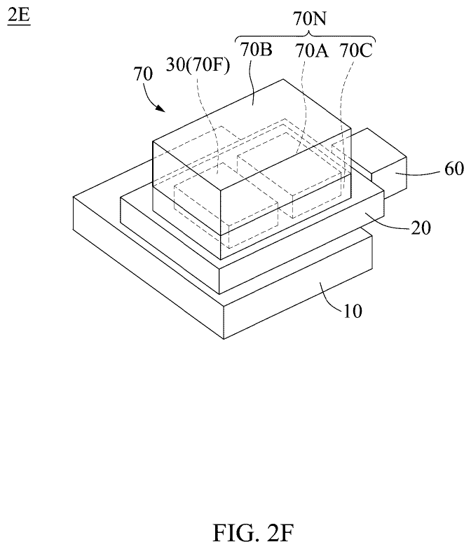

FIG. 2 is a cross-section of an electronic device 1 in accordance with some arrangements of the present disclosure. The electronic device 1 may include a substrate 10, a photonic component 20, an electronic component 50, an optical component 60, a reinforcement module 70, a heat sink 80, and electrical contacts 91. In some arrangements, the electronic device 1 may be or include an optoelectronic package. The electronic device 1 may be at least one of the optical transmitter module 1010 and the optical receiving module 1020 illustrated in FIG. 1A.

The substrate 10 may support the photonic component 20 and the electronic component 50. The substrate 10 may include, for example, a printed circuit board, such as a paper-based copper foil laminate, a composite copper foil laminate, or a polymer-impregnated glass-fiber-based copper foil laminate. The substrate 10 may include an interconnection structure, such as a plurality of conductive traces and a plurality of conductive vias. In some embodiments, the substrate 10 includes a ceramic substrate, a metal plate, an organic substrate, or a leadframe. In some embodiments, the substrate 10 may include a two-layer substrate which includes a core layer and a conductive material and/or structure disposed on an upper surface and a bottom surface of the substrate 10. The conductive material and/or structure may include a plurality of conductive traces. In some arrangements, the substrate 10 includes conductive pads 110 and 130.

The photonic component 20 may be disposed over and electrically connected to the substrate 10. The photonic component 20 may have a surface 202 facing the substrate 10 and a surface 201 opposite to the surface 202. The surface 201 may be an active surface. The surface 202 may be a backside surface or a passive surface. In some arrangements, the photonic component 20 is configured to optically couple to one or more optical components (e.g., the optical component 60). In some arrangements, the photonic component 20 is configured to optically couple to one or more optical components (e.g., the optical component 60) by edge coupling. The photonic component 20 may include a portion 20P that is at least partially free from vertically overlapping the substrate 10. The photonic component 20 (or the portion 20P) may overhang the substrate 10 in a cross-sectional view perspective. The photonic component 20 may be or include a photonic integrated circuit (PIC), a laser diode, a receiver, a waveguide, a photodetector, a photodiode, a semiconductor optical amplifier (SOA), a grating coupler, a fiber coupling structure, an optical modulator (e.g., Mach-Zehnder modulator or microring modulator), or a combination thereof.

In some arrangements, the photonic component 20 includes a substrate layer 200, conductive pads 210 and 220, barrier layers 212 and 222, conductive layers 210c, 220c, and 211, conductive vias 20v, an optical channel 240, and dielectric layers 261, 262, and 263. The substrate layer 200 may be or include a semiconductor layer, e.g., a silicon layer. The conductive layers 211 may be formed on the conductive pads 210, the barrier layers 212 may be formed on the conductive layers 211, and the barrier layers 222 may be formed on the conductive pads 220. The conductive layer 210c may be or include a circuit layer. The circuit layer may include one or more circuits configured to provide a photoelectric conversion. The conductive vias 20v may electrically connect the conductive layer 210c to the conductive layer 220c. The conductive vias 20v may be referred to as through silicon vias (TSVs). The conductive layer 220c may be electrically connected to the conductive pads 220. The optical channel 240 may be configured to optically couple to the optical component 60. The optical channel 240 may be or include an optical waveguide. The conductive pads 210 and 220, the conductive layers 210c, 220c, and 211, and the conductive vias 20v may include one or more conductive materials such as a metal or metal alloy. Examples include gold (Au), silver (Ag), aluminum (Al), copper (Cu), or an alloy thereof. The barrier layers 212 and 222 may include nickel (Ni). The photonic component 20 may have a thickness T1 equal to or less than about 100 μm, 80 μm, 60 μm, or 50 μm. The thickness T1 may be about 50 μm to about 100 μm.

The electronic component 50 may be disposed over and electrically connected to the substrate 10. The electronic component 50 may have a surface 502 facing the substrate 10 and a surface 501 opposite to the surface 502. The surface 501 may be an active surface. The surface 502 may be a backside surface or a passive surface. In some arrangements, the electronic component 50 includes conductive pads 520 exposed by the surface 501. In some arrangements, the electronic component 50 is electrically connected to the photonic component 20 through the substrate 10. In some arrangements, the electronic component 50 may be or include a processing component, e.g., an ASIC, an FPGA, a GPU, or the like, or a combination thereof.

The optical component 60 may be optically coupled to the photonic component 20. In some arrangements, the photonic component 20 (or the optical channel 240) is configured to optically couple to the optical component 60. In some arrangements, the optical component 60 includes one or more optical fibers. In some arrangements, the optical component 60 is or includes an optical fiber array unit (FAU).

The reinforcement module 70 may be disposed over the surface 201 of the photonic component 20. In some arrangements, the reinforcement module 70 is connected to the photonic component 20. In some arrangements, the reinforcement module 70 is configured to constructing a continuous structure in a direction (e.g., x-axis) substantially parallel to the surface 201 of the photonic component 20. In some arrangements, the reinforcement module 70 is configured to reduce a deformation of the photonic component 20. In some arrangements, the reinforcement module 70 is configured to reduce a warpage of the photonic component 20. In some arrangements, the reinforcement module 70 is configured to apply a supporting force along the surface 201 of the photonic component 20 continuously to prevent the photonic component 20 from being cracked. In some arrangements, a projection of the reinforcement module 70 on the surface 201 of the photonic component 20 is greater than about 70%, 75%, 80%, 85%, or 90% of the surface 201 of the photonic component 20 in a cross-sectional view perspective.

In some arrangements, the reinforcement module 70 includes a functional element 70F and a non-functional element 70N. In some arrangements, the functional element 70F includes a logic circuit. In some arrangements, the non-functional element 70N includes one or more dummy element free of a logic circuit, for example, dummy dies.

In some arrangements, the functional element 70F and the non-functional element 70N collectively construct a continuous structure in a direction (e.g., x-axis) substantially parallel to the surface 201 of the photonic component 20. In some arrangements, the non-functional element 70N directly contacts the functional element 70F. In some arrangements, the functional element 70F is between and connected to the surface 201 of the photonic component 20 and a portion of the non-functional element 70N. In some arrangements, the portion of the non-functional element 70N is configured to provide a thermal channel TC1 substantially perpendicular to the optical channel 240 of the photonic component 20.

The heat sink 80 may be disposed over the reinforcement module 70. In some arrangements, the heat sink 80 is connected to the reinforcement module 70 through an adhesive layer 95. The adhesive layer 95 may be or include an insulating adhesive. The adhesive layer 95 may be or include a die attach film (DAF). The adhesive layer 95 may include a thermal interface material (TIM). The heat sink 80 may be, for example, a pipe, a fin-type heat sink, a planar heat sink, a liquid cooling tube, or a thermal vapor compressor (TVC).

The electrical contacts 91 may be disposed over the substrate 10. In some arrangements, the electrical contacts 91 are encapsulated by one or more protective elements 91u. In some arrangements, the conductive pads 110 of the substrate 10 are electrically connected to the conductive pads 220 of the photonic component 20 through some of the electrical contacts 91. In some arrangements, the conductive pads 130 of the substrate 10 are electrically connected to the conductive pads 520 of the electronic component 50 through some of the electrical contacts 91. Some of the electrical contacts 91 that support the reinforcement module 70 may be dummy bumps configured not to provide electrical connection. Some of the electrical contacts 91 that support the reinforcement module 70 may electrically connect the substrate 10 to the photonic component 20. The electrical contacts 91 that electrically connect the substrate 10 to the photonic component 20 may further electrically connect to the functional element 70F of the reinforcement module 70. The electrical contacts 91 may be or include solder balls. In some arrangements, the electrical contacts 91 include controlled collapse chip connection (C4) bumps, a ball grid array (BGA), or a land grid array (LGA). The protective element 91u may be or include an underfill.

The photonic component 20 requires to be relatively thin to allow the formation of the conductive vias 20v within the photonic component 20, so as to allow the photonic component 20 to serve as an interposer that connects the electronic component 30 to the substrate 10. However, the relatively thin photonic component 20 may suffer from warpage due to its relatively low structural strength. As a result, the optical channel 240 (or the waveguide) of the photonic component 20 may warp or bend along with the warpage of the photonic component 20, and thus optical alignment shift between the optical channel 240 and the optical component 60 may occur. Moreover, the photonic component 20 may be further deformed seriously and thereby damaged or cracked due to its relatively low structural strength.

According to some arrangements of the present disclosure, the reinforcement module 70 is configured to construct a continuous structure in a direction (e.g., x-axis) substantially parallel to the surface 201 of the photonic component 20, the structural strength of the entire photonic component 20 can be increased significantly. Therefore, the warpage can be reduced, the optical alignment can be improved, and the reliability of the electronic device 1 can be increased.

In addition, according to some arrangements of the present disclosure, the reinforcement module 70 is configured to construct a continuous structure over the surface 201 and extending continuously from a center region toward the portion 20P of the photonic component 20 that is not supported by the substrate 10. Therefore, the structural strength of the photonic component 20 can be uniformly increased by being connected to the reinforcement module 70. Therefore, the structural strength of the entire photonic component 20 is substantially uniformly increased without any weak point, such that the photonic component 20 can be prevented from being damaged by unbalanced force applied on local regions (e.g., the weight of the overhang portion 20P) to the photonic component 20.

Furthermore, according to some arrangements of the present disclosure, a projection of the reinforcement module 70 on the surface 201 of the photonic component 20 is greater than about 70%, 75%, 80%, 85%, or 90% of the surface 201 of the photonic component 20 in a cross-sectional view perspective. With such design, the reinforcement module 70 covers a relatively large range of the surface 201 of the photonic component 20. Therefore, the reinforcement module 70 can improve the uniformity of the structural strength of the entire photonic component 20 and the integrity of the entire electronic device 1, thereby increasing the reliability of the electronic device 1.

Moreover, according to some arrangements of the present disclosure, the reinforcement module 70 includes a functional element 70F including a logic circuit and a non-functional element 70N free of a logic circuit. Therefore, the reinforcement module 70 can provide both electrical and reinforcing functions.

FIG. 2A is a cross-section of an electronic device 2A in accordance with some arrangements of the present disclosure. FIG. 2B is a perspective view of an electronic device 2A in accordance with some arrangements of the present disclosure. In some arrangements, FIG. 2B shows a perspective view of the electronic device 2A illustrated in FIG. 2A. Please be noted that some elements are omitted in FIG. 2B for clarity. The electronic device 2A is similar to the electronic device 1, and the differences therebetween are described as follows.

In some arrangements, the reinforcement module 70 includes a functional element 70F and a non-functional element 70N collectively constructing a continuous structure in a direction (e.g., x-axis) substantially parallel to the surface 201 of the photonic component 20. In some arrangements, the functional element 70F includes an electronic component 30. In some arrangements, the non-functional element 70N includes reinforcement elements 70A and 70B and an encapsulant 70C. In some arrangements, a projection of the reinforcement module 70 (e.g., the electronic component 30, the reinforcement elements 70A and 70B, and the encapsulant 70C) on the surface 201 of the photonic component 20 is greater than about 70%, 75%, 80%, 85%, or 90% of the surface 201 of the photonic component 20 in a cross-sectional view perspective.

In some arrangements, the reinforcement module 70 defines a gap G1 vertically overlapped with the photonic component 20 and a portion (e.g., the reinforcement element 70B) of the non-functional element 70N. In some arrangements, the gap G1 is defined by the functional element 70F (or the electronic component 30) and a portion (e.g., the reinforcement element 70A) of the non-functional element 70N. In some arrangements, a portion (e.g., the reinforcement element 70B) of the non-functional element 70N is configured to provide a thermal channel TC1 substantially perpendicular to the optical channel 240 of the photonic component 20.

In some arrangements, the electronic component 30 is between and connected to the surface 201 of the photonic component 20 and a portion (e.g., the reinforcement element 70B) of the non-functional element 70N. In some arrangements, the electronic component 30 is disposed over the electrically connected to the photonic component 20. In some arrangements, the electronic component 30 is electrically connected to the substrate 10 through the conductive vias 20v in the photonic component 20. In some arrangements, the electronic component 30 includes conductive pads 310 and 320 and a dielectric layer 310d. The conductive pad 310 may be referred to as a conductive pillar partially filled in an opening defined by the dielectric layer 310d. The conductive pads 310 may include Au, Ag, Al, Cu, Ni, or an alloy thereof. In some arrangements, the electronic component 30 is electrically connected to the photonic component 20 through the conductive pad 310, connection elements 92, the barrier layers 212, the conductive layers 211, and the conductive pads 210. The connection elements 92 may include conductive bumps. The connection elements 92 may be encapsulated by a protective element 92u. The protective element 92u may include an underfill. In some embodiments, the underfill includes an epoxy resin, a molding compound (e.g., an epoxy molding compound or other molding compound), polyimide, a phenolic compound or material, a material including a silicone dispersed therein, or a combination thereof. The electronic component 30 may be or include an electronic integrated circuit (EIC). In some arrangements, the electronic component 30 includes a logic circuit. In some arrangements, the electronic component 30 includes a modulator driver (DRV), a trans-impedance amplifier (TIA), or a combination thereof. The electronic component 30 may have a thickness T2 equal to or greater than the thickness T1 of the photonic component 20.

In some arrangements, the reinforcement element 70A is connected to the photonic component 20. In some arrangements, the reinforcement element 70A is connected to the photonic component 20 through an electrically isolated connection element. The electrically isolated connection element may include a dummy connection element. In some arrangements, the reinforcement element 70A includes pads 710 and 720 and a dielectric layer 710d. The pad 710 may be partially filled in an opening defined by the dielectric layer 710d. In some arrangements, the pad 710 (also referred to as “a dummy conductive pad”, “a dummy conductive bump” or “an electrically isolated pad”) of the reinforcement element 70A is connected to the conductive pad 220 through a connection element 92. The connection element 92 that connects to the pad 710 may be a dummy connection element or an electrically isolated pad. The pads 710 may include Au, Ag, Al, Cu, Ni, or an alloy thereof.

In some arrangements, the reinforcement element 70A includes a discrete component. In some arrangements, the reinforcement element 70A is distinct from the photonic component 20. In some arrangements, the reinforcement element 70A is free of a logic circuit. In some arrangements, the reinforcement element 70A includes a dummy substrate (e.g., a dummy silicon substrate). In some arrangements, the reinforcement element 70A includes a dummy die. In some arrangements, the reinforcement element 70A includes a dummy die free of a logic circuit. The reinforcement element 70A may have a thickness T4A equal to or greater than the thickness T1 of the photonic component 20. The thickness T4A of the reinforcement element 70A may be substantially the same as the thickness T2 of the electronic component 30.

In some arrangements, the reinforcement element 70B is disposed over the electronic component 30 and the reinforcement element 70A. In some arrangements, the reinforcement element 70B is supported by the electronic component 30 and the reinforcement element 70A. In some arrangements, the reinforcement element 70B vertically overlaps the gap G1 between the electronic component 30 and the reinforcement element 70A. In some arrangements, the reinforcement element 70B is connected to the electronic component 30 through a solder-free conductive structure. The solder-free conductive structure between the reinforcement element 70B and the electronic component 30 may include the conductive pad 320, a connection element 97, and a pad 730 of the reinforcement element 70B. In some arrangements, the reinforcement element 70B is connected to the reinforcement element 70A through a solder-free conductive structure. The solder-free conductive structure between the reinforcement element 70B and the reinforcement element 70A may include the pad 720, a connection element 97, and a pad 730 of the reinforcement element 70B. In some arrangements, the connection element 97 is free of a solder material. In some arrangements, the connection element 97 includes an alloy or an intermetallic compound (IMC) layer. In some arrangements, the connection element 97 between the reinforcement element 70B and the electronic component 30 includes an IMC layer formed of metals from the pad 730 and the conductive pad 320 and has a thickness T5A. In some arrangements, the connection element 97 between the reinforcement element 70B and the reinforcement element 70A includes an IMC layer formed of metals from the pad 730 and the pad 720 and has a thickness T5B.

In some arrangements, the reinforcement element 70B includes a discrete component. In some arrangements, the reinforcement element 70B is distinct from the photonic component 20, the electronic component 30, and the reinforcement element 70A. In some arrangements, the reinforcement element 70B is free of a logic circuit. In some arrangements, the reinforcement element 70B includes a dummy substrate (e.g., a dummy silicon substrate). In some arrangements, the reinforcement element 70B includes a dummy die. In some arrangements, the reinforcement element 70B includes a dummy die free of a logic circuit. The reinforcement element 70B may have a thickness T4B equal to or greater than the thickness T1 of the photonic component 20. The thickness T4B of the reinforcement element 70B may be substantially the same as or greater than the thickness T4A of the reinforcement element 70A.

According to some arrangements of the present disclosure, the reinforcement element 70B is connected to the reinforcement element 70A and the electronic component 30 through solder-free conductive structures. Since solders are not used to bond conductive pads from the reinforcement element 70B and the conductive pads from the reinforcement element 70A and the electronic component 30, the solder-free conductive structures formed of metal-bonded structures have relatively small thicknesses T5A and T5B, and thus the thickness or the height of the electronic device 2A can be reduced. In addition, since no solders are used, underfills that serve to protect the solders from oxidation or damages are not required, and thus delamination issues caused by CTE (coefficient of thermal expansion) mismatch between the underfills and the solders can be prevented.

In addition, according to some arrangements of the present disclosure, the solder-free conductive structures have relatively large widths with relatively small gaps formed therebetween. Therefore, the connection of the reinforcement element 70B to the reinforcement element 70A and the electronic component 30 can be enhanced, heat dissipation effects can be increased, and the relatively small gaps between the solder-free conductive structures allow the metal materials to overflow when being heated in the manufacturing process.

FIG. 2C is a cross-section of an electronic device 2C in accordance with some arrangements of the present disclosure. FIG. 2D is a perspective view of an electronic device 2C in accordance with some arrangements of the present disclosure. In some arrangements, FIG. 2D shows a perspective view of the electronic device 2C illustrated in FIG. 2C. Please be noted that some elements are omitted in FIG. 2D for clarity. The electronic device 2C is similar to the electronic device 1 and/or the electronic device 2A, and the differences therebetween are described as follows.

In some arrangements, the non-functional element 70N directly contacts the functional element 70F. In some arrangements, the non-functional element 70N includes the encapsulant 70C that directly contacts the functional element 70F (or the electronic component 30). In some arrangements, the encapsulant 70C is spaced apart from the photonic component 20.

In some arrangements, the reinforcement element 70A and the electronic component 30 are encapsulated by the encapsulant 70C. In some arrangements, the solder-free conductive structure (e.g., the conductive pad 320, the connection element 97, and the pad 730) between the reinforcement element 70B and the electronic component 30 is exposed by the encapsulant 70C. In some arrangements, the solder-free conductive structure (e.g., the pad 720, the connection element 97, and the pad 730) between the reinforcement element 70B and the reinforcement element 70A is exposed by the encapsulant 70C. In some arrangements, an upper surface 301 of the functional element 70F (or the electronic component 30) is substantially aligned with an upper surface 70A1 of the reinforcement element 70A. In some arrangements, an upper surface 70C1 of the encapsulant 70C is substantially aligned with the upper surface 301 of the functional element 70F (or the electronic component 30) and the upper surface 70A1 of the reinforcement element 70A.

According to some arrangements of the present disclosure, the electronic component 30 and the reinforcement element 70A are integrated by the encapsulant 70C to form an intermediate reinforcement module, and thus such intermediate reinforcement module can be connected or bonded to the photonic component 20 in a single operation. Therefore, the impact on the thinned photonic component 20 caused by external forces due to the connection or bonding operations can be reduced because the number of the connection or bonding operations is decreased, and the manufacturing process can be simplified.

FIG. 2E is a cross-section of an electronic device 2E in accordance with some arrangements of the present disclosure. FIG. 2F is a perspective view of an electronic device 2E in accordance with some arrangements of the present disclosure. In some arrangements, FIG. 2F shows a perspective view of the electronic device 2E illustrated in FIG. 2E. Please be noted that some elements are omitted in FIG. 2F for clarity. The electronic device 2E is similar to the electronic device 1 and/or the electronic device 2A, and the differences therebetween are described as follows.

In some arrangements, the encapsulant 70C encapsulates the electronic component 30, the reinforcement elements 70A and 70B, the solder-free conductive structure (e.g., the conductive pad 320, the connection element 97, and the pad 730) between the reinforcement element 70B and the electronic component 30, and the solder-free conductive structure (e.g., the pad 720, the connection element 97, and the pad 730) between the reinforcement element 70B and the reinforcement element 70A. In some arrangements, the electronic component 30 is between and connected to the surface 201 of the photonic component 20 and a portion (e.g., the reinforcement element 70B and the encapsulant 70C) of the non-functional element 70N.

In some arrangements, the encapsulant 70C contacts the electronic component 30 and the reinforcement elements 70A and 70B. In some arrangements, the thickness T2 of the functional element 70F (or the electronic component 30) is different from the thickness T4A of the reinforcement element 70A. In some arrangements, the upper surface 301 of the functional element 70F (or the electronic component 30) and the upper surface 70A1 of the reinforcement element 70A are encapsulated by the encapsulant 70C. In some arrangements, a lateral side 70B2 of the reinforcement element 70B is substantially aligned with a lateral side 70C2 of the encapsulant 70C.

In some arrangements, the reinforcement elements 70A and 70B, the encapsulant 70C encapsulates the electronic component 30, and the solder-free conductive structures may collectively construct the reinforcement module 70. In some arrangements, the reinforcement module 70 further includes connection elements 310v, a dielectric layer 330d, and pads 330. In some arrangements, the connection elements 310v penetrate openings of the dielectric layer 330d to connect the pads 330 to the conductive pads 310 and the pads 710. In some arrangements, the pads 330 are connected to the connection elements 92 and encapsulated by the protective element 92u.

According to some arrangements of the present disclosure, the reinforcement elements 70A and 70B, the encapsulant 70C encapsulates the electronic component 30, and the solder-free conductive structures are integrated to form the reinforcement module 70, and thus the integrated reinforcement module 70 can be connected or bonded to the photonic component 20 in a single operation. Therefore, the impact on the thinned photonic component 20 caused by external forces due to the connection or bonding operations can be reduced because the number of the connection or bonding operations is decreased, and the manufacturing process can be simplified.

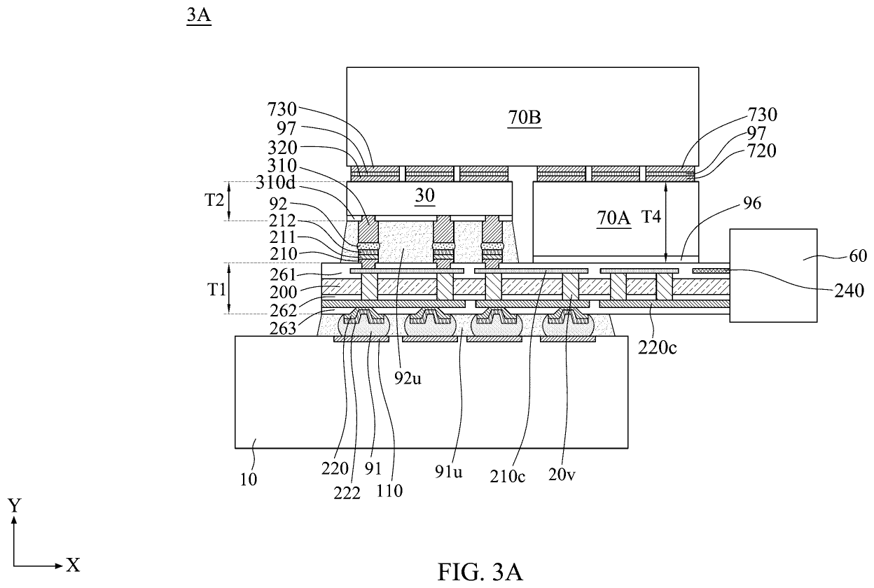

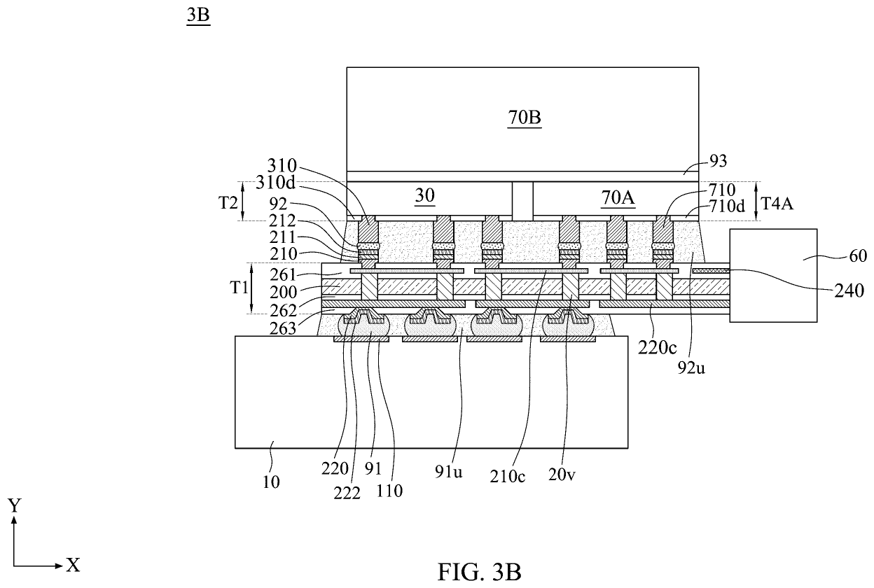

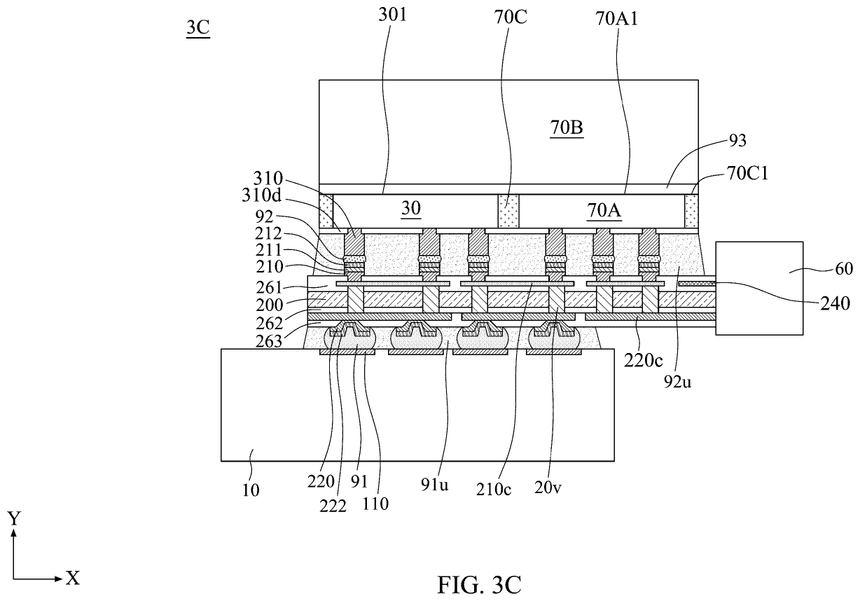

FIG. 3A is a cross-section of an electronic device 3A in accordance with some arrangements of the present disclosure. The electronic device 3A is similar to the electronic device 1 and/or the electronic device 2A, and the differences therebetween are described as follows.

In some arrangements, the reinforcement element 70A is connected to the photonic component 20 through an electrically isolated connection element. The electrically isolated connection element may include a dummy connection element. In some arrangements, a bottom surface of the reinforcement element 70A is connected to the dielectric layer 261 of the photonic component 20 through a connection element 96. The connection element 96 that connects to the reinforcement element 70A may be an adhesive layer (e.g., DAF). According to some arrangements of the present disclosure, the connection element 96 between the protective element 92u and the optical component 60 can prevent the material of the protective element 92u from overflowing or bleeding toward and contaminating the optical component 60 during manufacturing processes.

FIG. 3B is a cross-section of an electronic device 3B in accordance with some arrangements of the present disclosure. The electronic device 3B is similar to the electronic device 1 and/or the electronic device 2A, and the differences therebetween are described as follows.

In some arrangements, the reinforcement element 70B is connected to the electronic component 30 and the reinforcement element 70A through an adhesive layer 93. The adhesive layer 93 may be or include an insulating adhesive. The adhesive layer 93 may be or include a die attach films (DAF). The adhesive layer 93 may include a thermal interface material (TIM). According to some arrangements of the present disclosure, the adhesive layer 93 (e.g., the TIM) is used to connect the reinforcement element 70B to the reinforcement element 70A and the electronic component 30, the processing steps can be simplified, the cost can be reduced, and the heat dissipation effect can be improved.

FIG. 3C is a cross-section of an electronic device 3C in accordance with some arrangements of the present disclosure. The electronic device 3C is similar to the electronic device 1 and/or the electronic device 2A, and the differences therebetween are described as follows.

In some arrangements, the reinforcement element 70B is connected to the electronic component 30, the reinforcement element 70A, and the encapsulant 70C through an adhesive layer 93. The adhesive layer 93 may be or include an insulating adhesive. The adhesive layer 93 may be or include a die attach films (DAF). The adhesive layer 93 may include a thermal interface material (TIM).

Simulation results are presented in Tables 1-2 below to show the advantageous effects of the electronic devices in accordance with some embodiments of the present disclosure. Tables 1-2 show the influences of the thicknesses T1 of the photonic component 20, the thickness T2 of the electronic component 30, the thickness T4A of the reinforcement element 70A, and the thickness T4B of the reinforcement element 70B on the warpage of the entire surface 201 (e.g., the region R1 illustrated in FIG. 2A) of the photonic component 20 and the warpage of an edge portion (e.g., the region R2 illustrated in FIG. 2A) at different temperatures (at room temperature (RT) and at an elevation temperature of 260° C.). Embodiments E1, E2, E3, and E4 refer to electronic devices having the reinforcement elements 70A and 70B, for example, including a structure similar to that shown in FIG. 2A and FIG. 2B, a structure similar to that shown in FIG. 2C and FIG. 2D, and/or a structure similar to that shown in FIG. 2E and FIG. 2F. Comparative embodiments C1a, C2a, C3a, and C4a refer to electronic devices without any reinforcement element. Comparative embodiments C1b, C2b, C3b, and C4b refer to electronic devices having the reinforcement element 70A and without the reinforcement element 70B. Please be noted that the photonic component of the electronic device of the embodiment E4 has a thickness of “N”, wherein N ranges from 50 μm to 150 μm, and the thicknesses of the embodiments and the comparative embodiments are all represented by N for comparison. In addition, please be noted that the photonic component of the electronic device of the comparative embodiment C3a has a warpage w at the region R1 at RT, wherein w ranges from 15 μm to 25 μm, and the warpage of the embodiments and the comparative embodiments are all represented by w for comparison.

TABLE 1

| | C1a | C1b | E1 | C2a | C2b | E2 |
|---|---|---|---|---|---|---|
| T1 | 1.4N | 1.4N | 1.4N | N | N | N |
| Width of the | 0.14N | 0.14N | 0.14N | 0.1N | 0.1N | 0.1N |
| conductive vias 20 v | | | | | | |
| T2 | 10.7N | 10.7N | 10.7N | 10.7N | 10.7N | 10.7N |
| T4A | — | 10.7N | 10.7N | — | 10.7N | 10.7N |
| T4B | — | — | 10.7N | — | — | 10.7N |
| Warpage | | | | | | |
| Region R1 at RT | +0.52w | +0.39w | +0.20w | +0.65w | +0.51w | +0.24w |
| Region R1 at 260° C. | +0.45w | +0.26w | −0.15w | +0.48w | +0.36w | −0.19w |
| Region R2 at RT | +0.26w | +0.16w | +0.05w | +0.27w | +0.16w | +0.06w |
| Region R2 at 260° C. | +0.12w | +0.07w | +0.04w | +0.13w | +0.07w | +0.04w |

TABLE 2

| | C3a | C3b | E3 | C4a | C4b | E4 |
|---|---|---|---|---|---|---|
| T1 | N | N | N | N | N | N |
| Width of the | 0.1N | 0.1N | 0.1N | 0.1N | 0.1N | 0.1N |
| conductive vias 20 v | | | | | | |
| T2 | 4.2N | 4.2N | 4.2N | N | N | N |
| T4A | — | 4.2N | 4.2N | — | N | N |
| T4B | — | — | 4.2N | — | — | N |
| Warpage | | | | | | |
| Region R1 at RT | +w | +0.90w | +0.64w | −0.80w | −0.99w | +0.38w |
| Region R1 at 260° C. | −0.22w | −0.26w | −0.31w | −0.38w | −0.47w | −0.34w |
| Region R2 at RT | +0.34w | +0.31w | +0.17w | −0.18w | −0.35w | +0.06w |
| Region R2 at 260° C. | −0.02w | −0.08w | −0.05w | −0.03w | −0.14w | −0.10w |

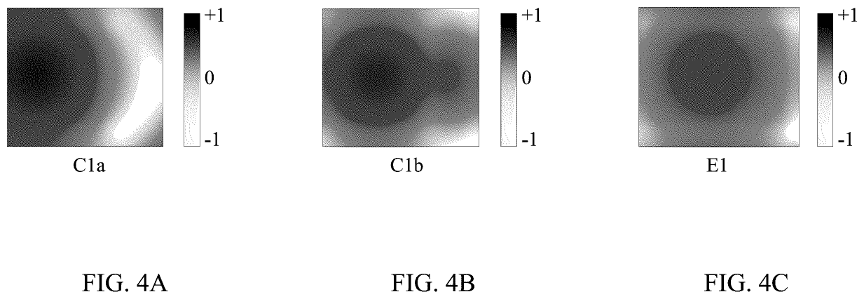

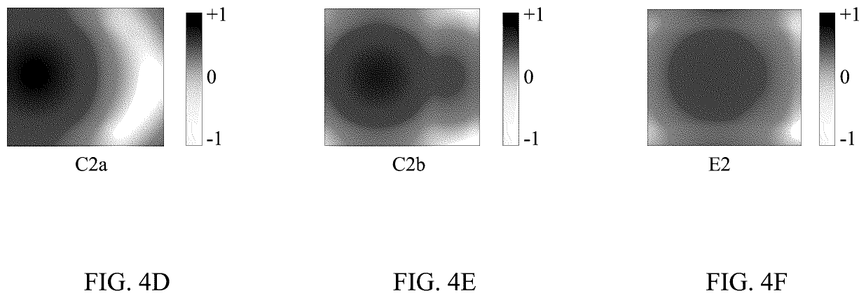

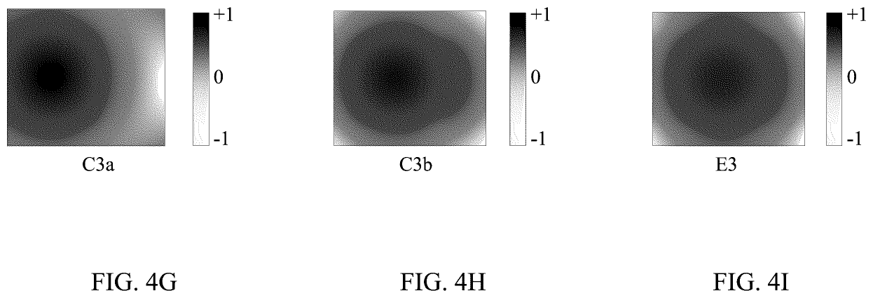

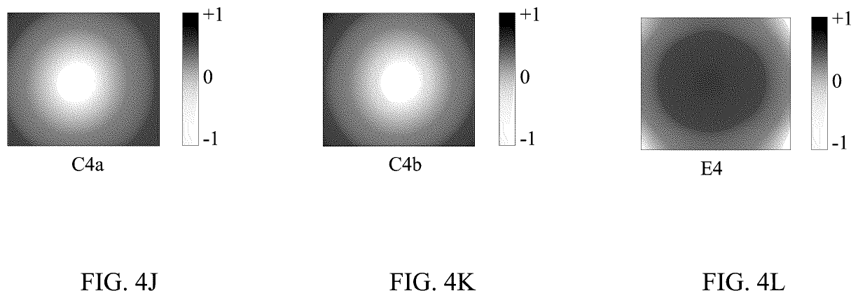

FIG. 4A, FIG. 4B, FIG. 4C, FIG. 4D, FIG. 4E, FIG. 4F, FIG. 4G, FIG. 4H, FIG. 4I, FIG. 4J, FIG. 4K, and FIG. 4L show simulation results of warpage of electronic devices in accordance with some arrangements of the present disclosure. In some arrangements, FIG. 4A, FIG. 4B, FIG. 4C, FIG. 4D, FIG. 4E, FIG. 4F, FIG. 4G, FIG. 4H, FIG. 4I, FIG. 4J, FIG. 4K, and FIG. 4L show the warpage of the surfaces 201 of the photonic components 20 from a top view perspective of the embodiments and the comparative embodiments listed in Tables 1-2.

As shown in Tables 1-2, the electronic devices with both of the reinforcement elements 70A and 70B are provided with relatively low warpage. For example, for the electronic devices having the same combination of thicknesses of components, the one with both of the reinforcement elements 70A and 70B have the lowest warpage. In addition, as shown in FIGS. 4A-4I, the electronic devices with both of the reinforcement elements 70A and 70B have not only the relatively low warpage but also the relatively uniform warpage distribution. For example, the surface 201 of the photonic component 20 of the comparative embodiment C1a has a relatively large warpage adjacent to a lateral edge (i.e., the left side of the image) of the surface 201 and a relatively small warpage adjacent to an opposite lateral edge (i.e., the right side of the image) of the surface 201. It indicates that the unbalanced external force (e.g., from the overhang of the photonic component 20 and optionally the weight of the optical component 60 adding to the overhang of the photonic component 20) generates a significant impact on formation the non-uniform warpage distribution.

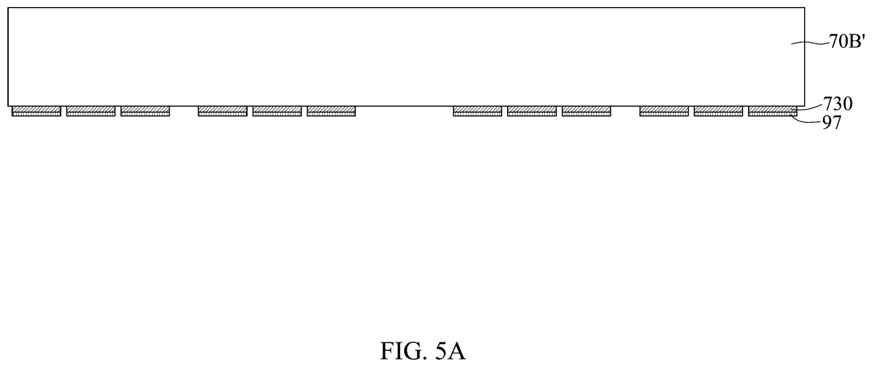

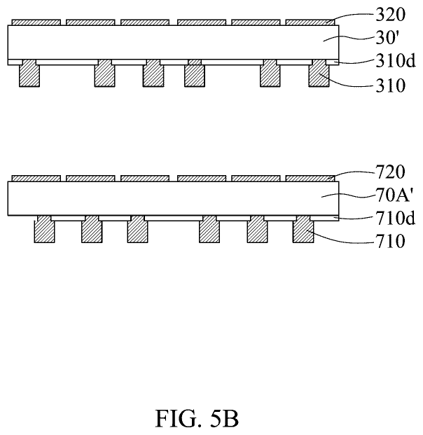

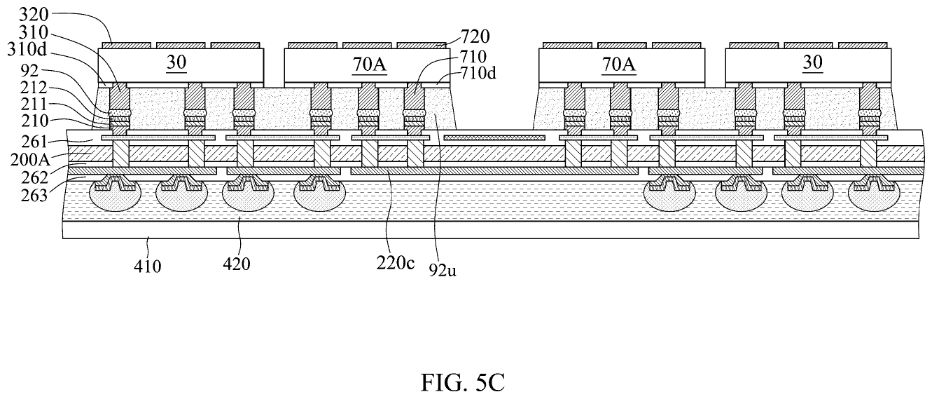

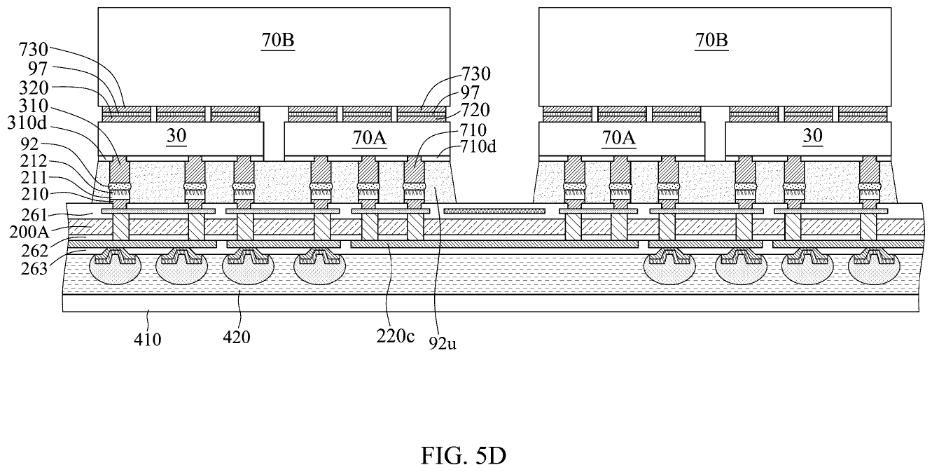

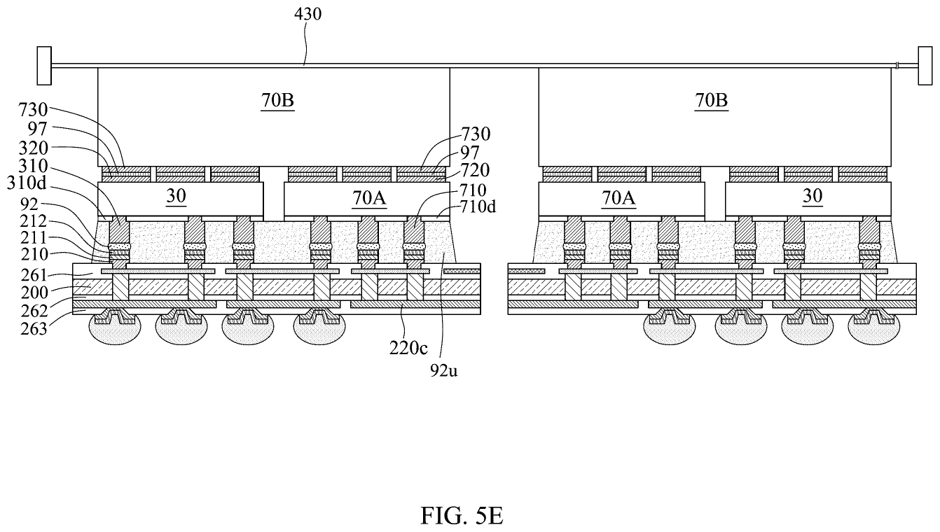

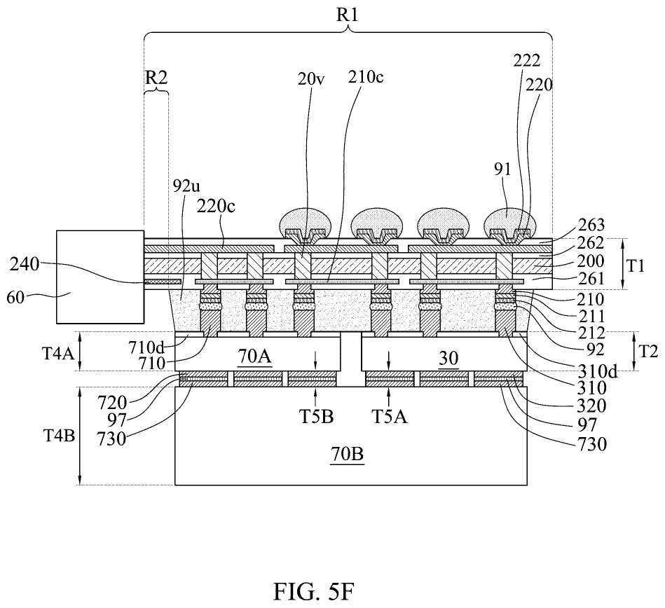

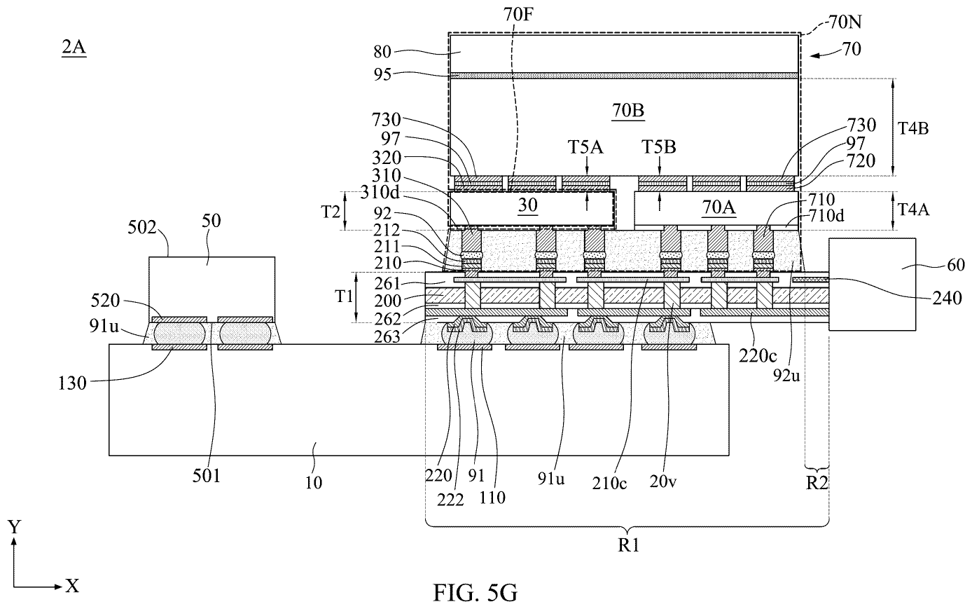

FIG. 5A, FIG. 5B, FIG. 5C, FIG. 5D, FIG. 5E, and FIG. 5G illustrate various stages of an exemplary method for manufacturing an electronic device 2A in accordance with some embodiments of the present disclosure.

Referring to FIG. 5A, a wafer level reinforcement element 70B′ including pads 730 and metal layers 97A formed on a surface thereof may be provided. In some arrangements, a thickness of the metal layers 97A is less than a thickness of the pads 730. In some arrangements, the metal layers 97A may be or include a metal material having a relatively low melting point. In some arrangements, the melting point of the metal layers 97A is lower than the melting point of the pads 730. The melting point of the metal layers 97A may be lower than 260° C., 200° C., 150° C., 130° C., or 100° C. The pads 730 may or include Au, Ag, Al, Cu, Ni, or an alloy thereof. The metal layers 97A may be or include gallium (Ga), indium (In), In—Sn alloy, or an alloy thereof.

Referring to FIG. 5B, a wafer level electronic component 30′ including a dielectric layer 310d and conductive pads 310 and 320 may be provided, and a wafer level reinforcement element 70A′ including a dielectric layer 710d and pads 710 and 720 may be provided. The conductive pads 310 and the pads 710 may be referred to as vias or pillars.

Referring to FIG. 5C, a wafer level photonic component including a substrate layer 200A, conductive pads 210 and 220, barrier layers 212 and 222, conductive layers 210c, 220c, and 211, conductive vias 20v, an optical channel 240A, and dielectric layers 261A, 262A, and 263A may be provided, and electrical contacts 91 may be disposed on the conductive pads 220. The above wafer level structure may be disposed over a carrier 410 with the electrical contacts 91 embedded in the gel layer 420 on the carrier 410. The carrier 410 may be a rigid carrier and configured to support the wafer level photonic component, and the gel layer 420 is configured to provide stress buffer and accommodating spaces for the electrical contacts 91. In some arrangements, a singulation operation may be performed on the wafer level electronic component 30′ to form a plurality of electronic components 30, a singulation operation may be performed on the wafer level reinforcement elements 70A′ to form a plurality of reinforcement elements 70A, and the electronic components 30 and the reinforcement elements 70A are disposed over and connected to the wafer level photonic component.

Referring to FIG. 5D, a singulation operation may be performed on the wafer level reinforcement elements 70B′ to form a plurality of reinforcement elements 70B, and the reinforcement elements 70B may be disposed over and connected to the electronic components 30 and the reinforcement elements 70A. In some arrangements, the metal layers 97A on the pads 730 may be connected to the conductive pads 320 and the pads 720 to connect the reinforcement elements 70B to the electronic components 30 and the reinforcement elements 70A. In some arrangements, a thermal treatment may be performed to melt the metal layers 97A and allow the melted metal layers 97A to form connection elements 97 each formed of an alloy layer or an IMC layer to bond the pad 730 to the conductive pads 320 and the pads 720. The thermal treatment may be performed under a temperature lower than 260° C., 200° C., 150° C., 130° C., or 100° C. The as-formed connection element 97 may have a melting point higher than the melting point of the metal layers 97A, the melting point of a solder material, the melting point of the pad 720, the melting point of the pad 730, and/or the melting point of the conductive pad 320.

According to some arrangements of the present disclosure, the carrier 410 can support the wafer level photonic component and prevent it from being cracked from relatively weak regions when bonding the connectors 40 to the wafer level photonic component. In addition, according to some arrangements of the present disclosure, the connection elements 97 having a relatively high melting point are formed by performing a thermal treatment on the metal layers 97A under a relatively low temperature. Therefore, the components/elements of the intermediate structure can be prevented from being damaged by heat during the relatively low-temperature thermal treatment on the metal layers 97A, and the as-formed connection elements 97 can have a relatively high stability when being subjected to heat during subsequent operations.

Referring to FIG. 5E, the structure illustrate in FIG. 5D may be disposed over a tape 430, and a singulation operation may be performed to form a plurality of photonic components 20. The gel layer 420 and the carrier 410 may be removed.

Referring to FIG. 5F, an optical component 60 may be connected to an edge portion of the photonic component 20. In some arrangements, each of the singulation structures illustrated in FIG. 5E may be disposed over and supported by a carrier or a tray, and then the photonic component 20 of each of the singulation structures is connected with an optical component 60. The reinforcement elements 70A and 70B provide a supporting force to increase the structural strength of the photonic component 20 so as to reduce warpage of the photonic component 20.

Referring to FIG. 5G, the photonic component 20 may be connected to a substrate 10 through the electrical contacts 91. In some arrangements, an electronic component 50 is connected to the substrate through the electrical contacts 91. In some arrangements, a heat sink 80 is further disposed over and connected to the reinforcement element 70B. As such, the electronic device 2A may be formed.

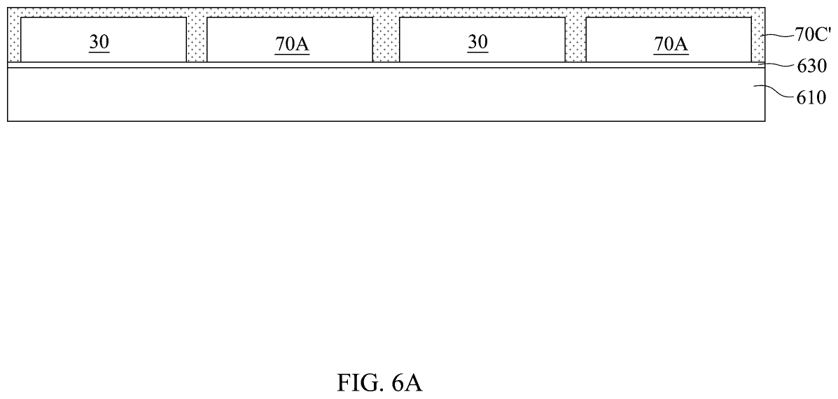

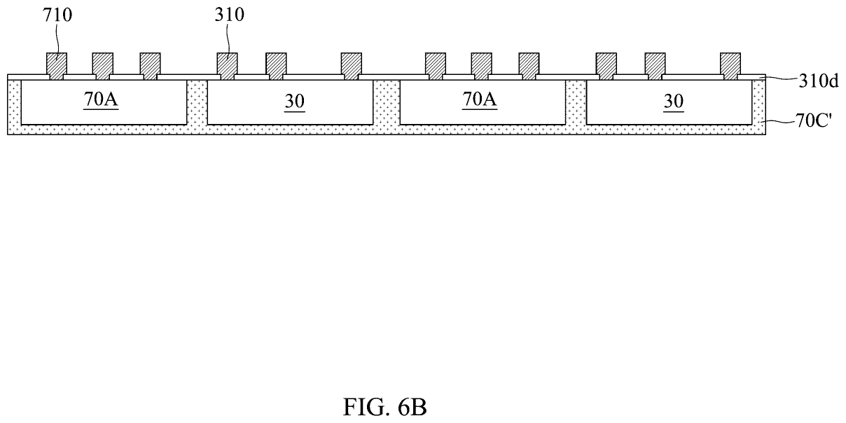

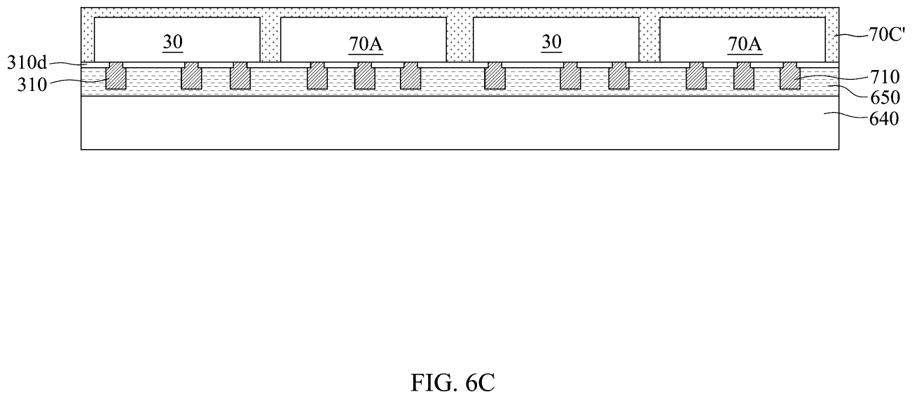

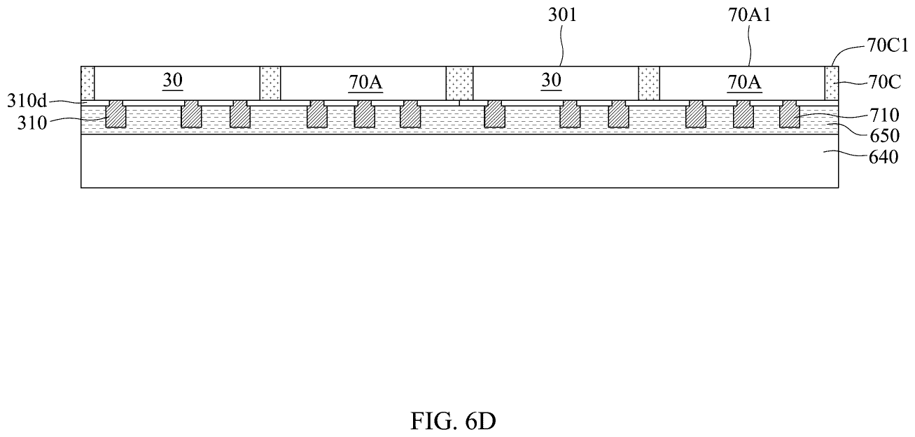

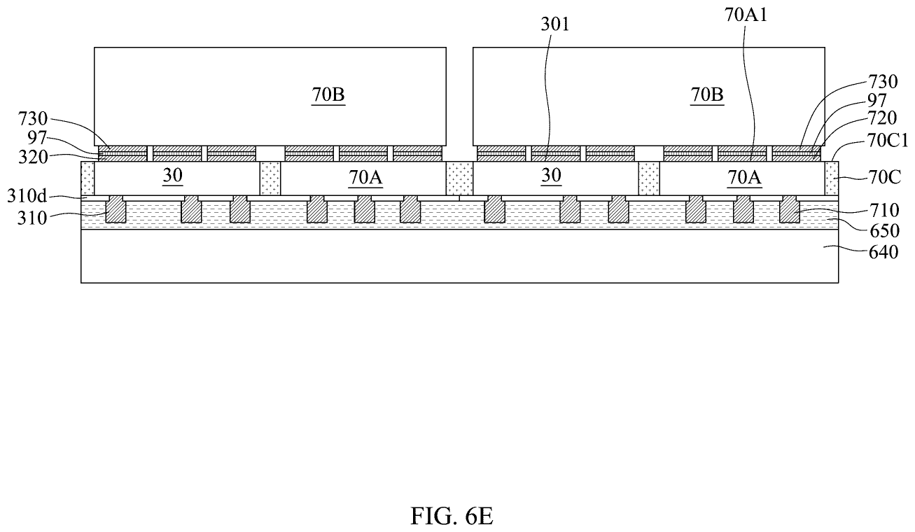

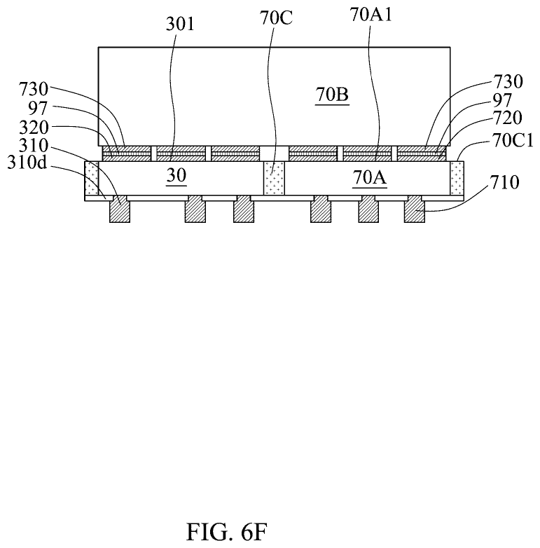

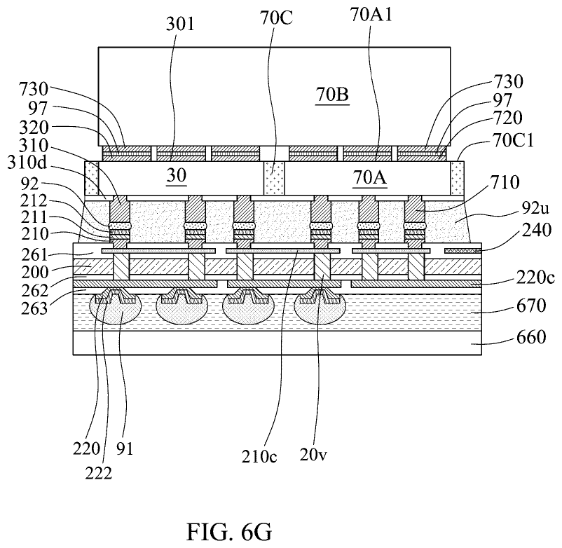

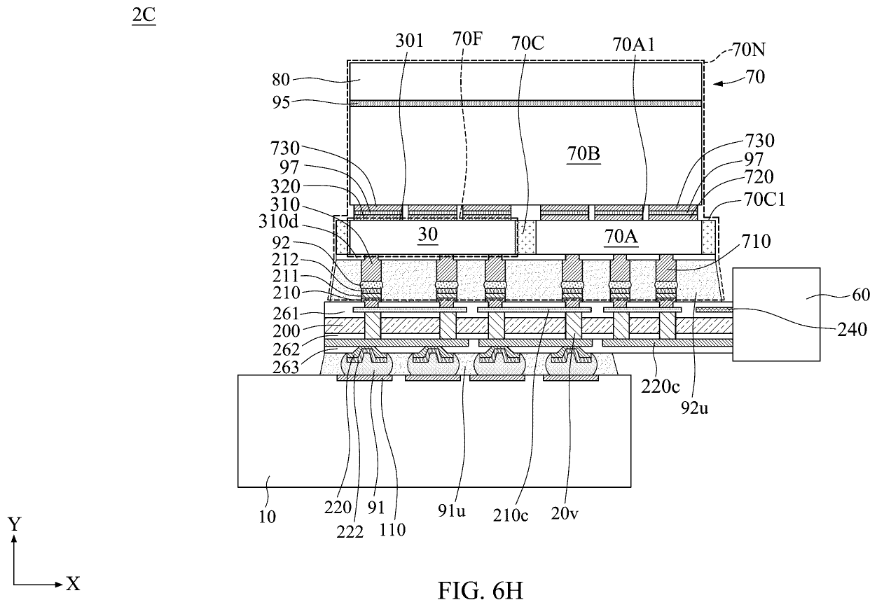

FIG. 6A, FIG. 6B, FIG. 6C, FIG. 6D, FIG. 6E, FIG. 6G, and FIG. 6H illustrate various stages of an exemplary method for manufacturing an electronic device 2C in accordance with some embodiments of the present disclosure.

Referring to FIG. 6A, electronic components 30 and reinforcement elements 70A may be disposed over a carrier 610 with a release tape 620, and an encapsulant 70C′ may be formed over the carrier 610 to encapsulate the electronic components 30 and the reinforcement elements 70A. The carrier 610 may be a wafer level rigid carrier and configured to support the electronic components 30 and the reinforcement elements 70A.

Referring to FIG. 6B, the carrier 610 and the release tape 620 may be removed, the encapsulated structure may be flipped over, and then a dielectric layer 310d, conductive pads 310, and pads 710 may be formed over the electronic components 30, the reinforcement elements 70A, and the encapsulant 70C′.

Referring to FIG. 6C, the structure illustrated in FIG. 6B may be flipped over and disposed over a carrier 640 with the conductive pads 310 and the pads 710 embedded in a gel layer 650 on the carrier 640. The carrier 640 may be a rigid carrier and configured to support the wafer level structure, and the gel layer 650 is configured to provide stress buffer and accommodating spaces for the conductive pads 310 and the pads 710.

Referring to FIG. 6D, a grinding operation may be performed to remove a portion of the encapsulant 70C′ to form thinned electronic components 30 and reinforcement elements 70A exposed by the encapsulant 70C. In some arrangements, upper surfaces 301 of the electronic components 30, upper surfaces 70A1 of the reinforcement elements 70A, and an upper surface 70C1 of the encapsulant 70C may be substantially aligned or coplanar.

Referring to FIG. 6E, operations similar to those illustrated in FIG. 5A and FIG. 5D may be performed to form a plurality of reinforcement elements 70B, and the reinforcement elements 70B may be disposed over and connected to the electronic components 30 and the reinforcement elements 70A.

Referring to FIG. 6F, the gel layer 650 and the carrier 640 may be removed, and the wafer level structure may be singulated to form a plurality of singulated structures.

Referring to FIG. 6G, operations similar to those illustrated in FIG. 5C may be performed to dispose a wafer level photonic component over a carrier 660 with the electrical contacts 91 embedded in a gel layer 670 on the carrier 660, and the above-mentioned singulated structures may be connected to the wafer level photonic component.

Referring to FIG. 6H, operations similar to those illustrated in FIG. 5E, FIG. 5F, and FIG. 5G may be performed to form the electronic device 2C as illustrated in FIG. 2C and FIG. 2D.

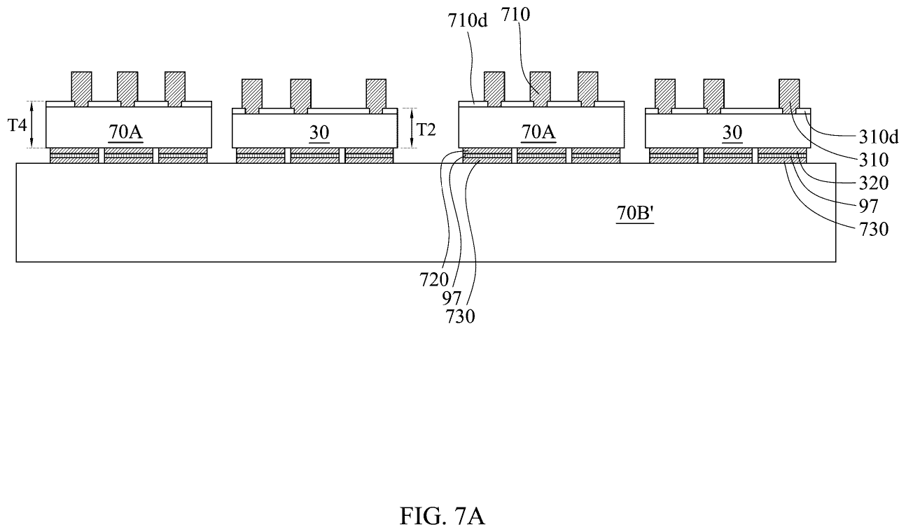

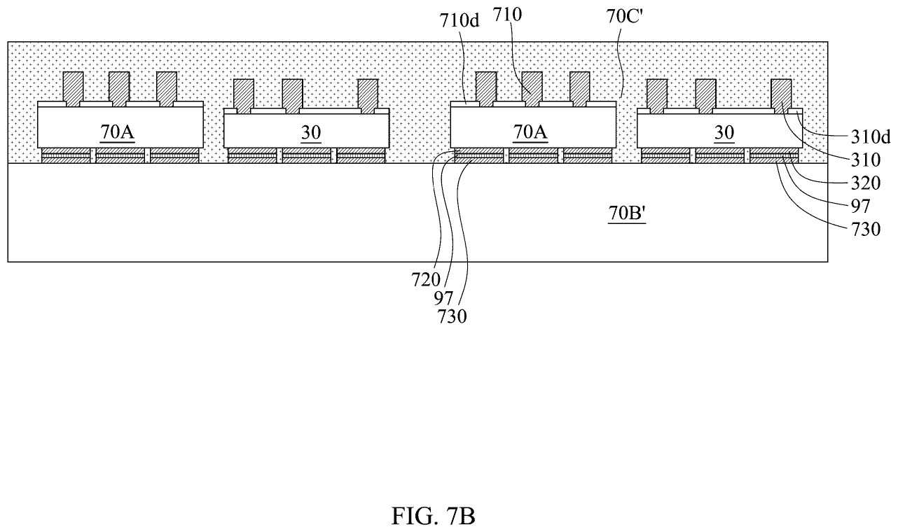

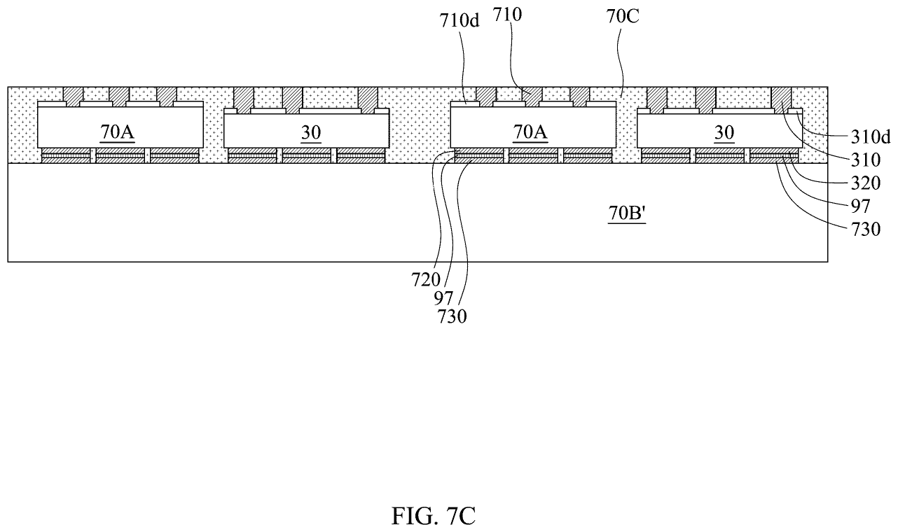

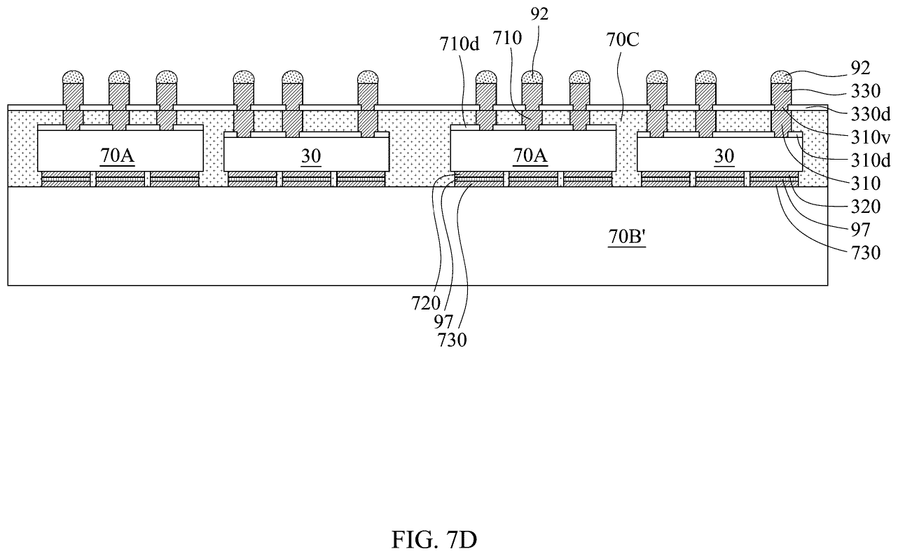

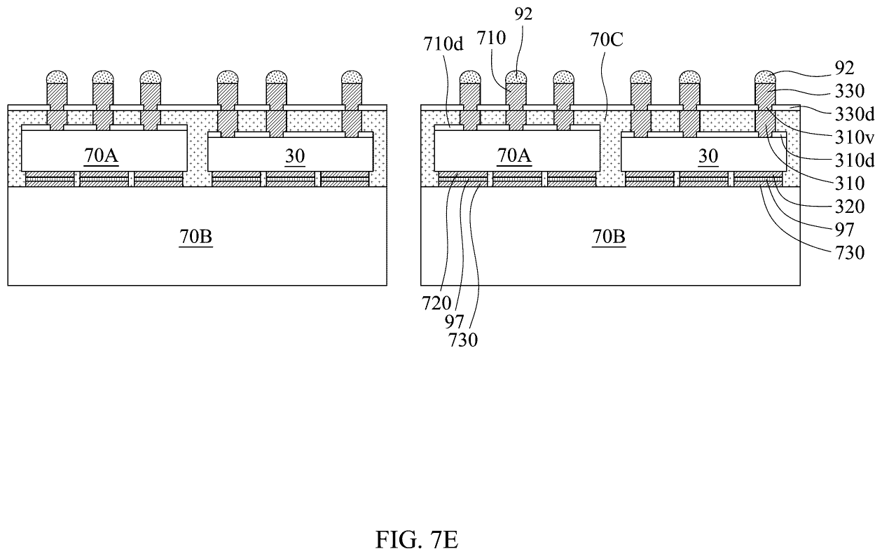

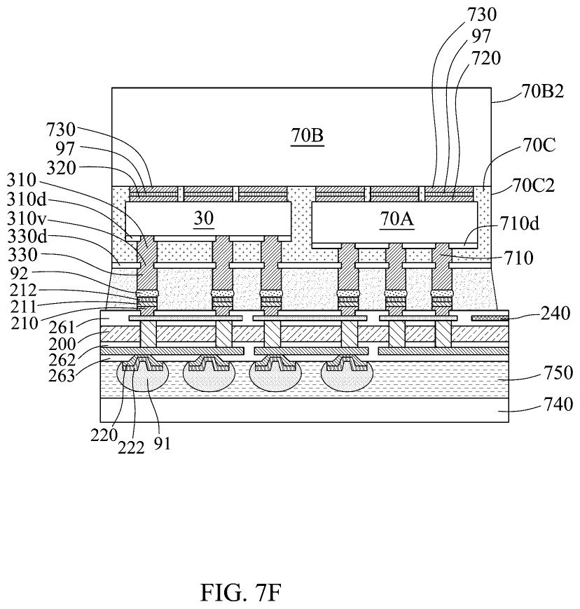

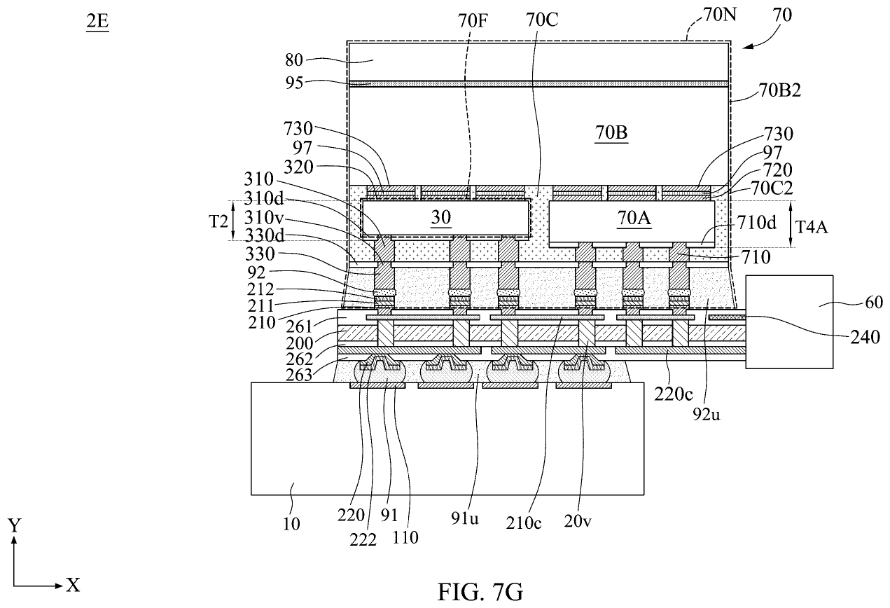

FIG. 7A, FIG. 7B, FIG. 7C, FIG. 7D, FIG. 7E, and FIG. 7G illustrate various stages of an exemplary method for manufacturing an electronic device 2E in accordance with some embodiments of the present disclosure.

Referring to FIG. 7A, operations similar to those illustrated in FIG. 5A may be performed to form a wafer level reinforcement element 70B′ including pads 730 and metal layers 97A, operations similar to those illustrated in FIG. 5B and FIG. 5C may be performed to form a plurality of electronic components 30 and a plurality of reinforcement elements 70A, and operations similar to those illustrated in FIG. 5D may be performed to connect the electronic components 30 and the reinforcement elements 70A to the wafer level reinforcement element 70B′.

Referring to FIG. 7B, an encapsulant 70C′ may be formed over the wafer level reinforcement element 70B′ to encapsulate the electronic components 30 and the reinforcement elements 70A.

Referring to FIG. 7C, a grinding operation may be performed to remove a portion of the encapsulant 70C′ to expose the conductive pads 310 and the pads 710 from the encapsulant 70C.

Referring to FIG. 7D, a dielectric layer 330d may be formed over the encapsulant 70C with openings exposing the conductive pads 310 and the pads 710, connection elements 310v may be formed in the openings to connect to the conductive pads 310 and the pads 710, and pads 330 may be formed over and connected to the connection elements 310v.

Referring to FIG. 7E, a singulation operation may be performed on the structure illustrated in FIG. 7D to form a plurality of singulated structures each including a reinforcement element 70B.

Referring to FIG. 7F, operations similar to those illustrated in FIG. 5C may be performed to dispose a wafer level photonic component over a carrier 740 with the electrical contacts 91 embedded in a gel layer 750 on the carrier 740, and the singulated structures illustrated in FIG. 7E may be connected to the wafer level photonic component. In some arrangements, the Referring to FIG. 7G, operations similar to those illustrated in FIG. 5E, FIG. 5F, and FIG. 5G may be performed to form the electronic device 2E as illustrated in FIG. 2E and FIG. 2F.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
a photonic component; and
a reinforcement module disposed over a first surface of the photonic component and configured to reduce a warpage of the photonic component,
wherein the reinforcement module comprises a functional element and a non-functional element collectively constructing a continuous structure in a direction substantially parallel to the first surface of the photonic component.

2. The electronic device as claimed in claim 1, wherein the functional element comprises a logic circuit.

3. The electronic device as claimed in claim 2, wherein the functional element is between and connected to the first surface of the photonic component and a portion of the non-functional element.

4. The electronic device as claimed in claim 3, wherein the portion of the non-functional element is configured to provide a thermal channel substantially perpendicular to an optical channel of the photonic component.

5. The electronic device as claimed in claim 1, wherein the non-functional element comprises a dummy die free of a logic circuit.

6. The electronic device as claimed in claim 1, wherein the reinforcement module defines a gap vertically overlapped with the photonic component and a first portion of the non-functional element.

7. The electronic device as claimed in claim 6, wherein the gap is defined by the functional element and a second portion of the non-functional element.

8. The electronic device as claimed in claim 7, wherein the first portion is supported by the second portion.

9. The electronic device as claimed in claim 5, wherein the non-functional element comprises an encapsulant encapsulates the function element and the dummy die.

10. An electronic device, comprising:
a photonic component; and
a reinforcement module configured to reduce a deformation of the photonic component, wherein the reinforcement module comprises a functional element and a first reinforcement element connected to the functional element.

11. The electronic device as claimed in claim 10, wherein the first reinforcement element is connected to the functional element through a solder-free conductive structure.

12. The electronic device as claimed in claim 11, wherein the reinforcement module further comprises an encapsulant, and the solder-free conductive structure is exposed by the encapsulant.

13. The electronic device as claimed in claim 10, wherein the reinforcement module further comprises an encapsulant encapsulating the functional element.

14. The electronic device as claimed in claim 13, wherein the reinforcement module further comprises a second reinforcement element supporting the first reinforcement element and encapsulated by the encapsulant.

15. The electronic device as claimed in claim 14, wherein an upper surface of the functional element is substantially aligned with an upper surface of the second reinforcement element.

16. The electronic device as claimed in claim 15, wherein an upper surface of the encapsulant is substantially aligned with the upper surface of the functional element and the upper surface of the second reinforcement element.

17. The electronic device as claimed in claim 14, wherein the first reinforcement element is encapsulated by the encapsulant.

18. The electronic device as claimed in claim 17, wherein a lateral side of the first reinforcement element is substantially aligned with a lateral side of the encapsulant.

19. An electronic device, comprising:
a photonic component; and
a reinforcement module comprising a first electronic component and disposed over the photonic component, wherein the reinforcement module is configured to apply a supporting force along a surface of the photonic component continuously to prevent the photonic component from being cracked.

20. The electronic device as claimed in claim 19, wherein the reinforcement module further comprises:
a first dummy silicon substrate disposed over the photonic component;
a second dummy silicon substrate supported by the first electronic component and the first dummy silicon substrate; and
an encapsulant encapsulating the first electronic component and the first dummy silicon substrate.
